(19) United States
(12) Patent Application Publication
(10) Pub. No.: US 2007/0145423 A1
(43) Pub. Date: Jun. 28, 2007

(54) CMOS Image Sensor and Manufacturing Method Thereof

(76) Inventor: Chang Hun Han, Icheon-Si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/612,661

(22) Filed: Dec. 19, 2006

(30) Foreign Application Priority Data
Dec. 28, 2005 (KR) 10-2005-0132339

(51) Int. Cl. H01L 27/148

(52) U.S. Cl. 257/233

(57) ABSTRACT

A CMOS (complementary metal oxide semiconductor) image sensor and method of fabricating the same is provided. The CMOS image sensor can include: a semiconductor substrate in which an active region and a device isolation region are defined; a photodiode region including a first region and a second region extending from the first region formed on the active region, wherein impurity ions of a first conductivity type and impurity ions of a second conductivity type are implanted in the first region, and impurity ions of the first conductivity type are implanted in the second region; and a transistor and an impurity diffusion region of a first conductivity type formed on a transistor region of the active region.

### RELATED APPLICATION

This application claims the benefit under 35 U.S.C. §119(e), of Korean Patent Application Number 10-2005-0132339 filed Dec. 28, 2005, which is incorporated herein by reference in its entirety.

### FIELD OF THE INVENTION

The present invention relates to a complementary metal oxide semiconductor (CMOS) image sensor and a method for manufacturing the same.

### BACKGROUND OF THE INVENTION

In general, an image sensor is a semiconductor device that transforms an optical image to electrical signals. The image sensor is generally classified as a charge coupled device (CCD) or a CMOS image sensor. A CCD type image sensor includes several MOS (metal oxide semiconductor) capacitors, closely positioned to one another, and electric charge carriers are transferred to or saved in the MOS capacitors.

On the other hand, a CMOS image sensor incorporates a switching mode by forming MOS transistors for each unit pixel with CMOS technology and using control circuits and signal-processing circuits in conjunction with the MOS transistors to sequentially detect the outputs of the photodiodes.

The CCD has various disadvantages, such as a complicated driving mode and high power consumption. It is also not possible to integrate a signal processing circuit on a single chip for a CCD due to the high number of mask processes. Currently, in order to overcome these disadvantages, many studies are being made of the development of the CMOS image sensor using sub-micron CMOS manufacturing technology.

The CMOS image sensor obtains an image by forming a photodiode and a MOS transistor within a unit pixel to detect signals in a switching mode. As mentioned above, because the CMOS image sensor makes use of CMOS manufacturing technology, the CMOS image sensor has low power consumption, as well as a manufacturing process requiring about 20 masks, compared with the CCD manufacturing process requiring 30 to 40 masks. As a result, the CMOS image sensor can integrate a signal processing circuit into a single chip. Accordingly the CMOS image sensor is used in various applications, such as digital still cameras (DSC), PC cameras, and mobile cameras.

The CMOS image sensor is classified as a 3T type, a 4T type or a 5T type according to the number of transistors formed in a unit pixel. The 3T type CMOS image sensor includes a single photodiode and three transistors, and the 4T type CMOS image sensor includes a single photodiode and four transistors. Hereinafter, a 3T type CMOS image sensor according to the related art will be explained with reference to the accompanying drawings.

FIG. 1 is an equivalent circuit diagram of a 3T type CMOS image sensor according to the related art.

As shown in FIG. 1, the unit pixel of the typical 3T type CMOS image includes one photodiode (PD) and three NMOS transistors T1, T2 and T3. The photodiode includes a cathode connected to the drain of the first NMOS transistor T1 and the gate of the second NMOS transistor T2.

Further, the sources of the first and second NMOS transistors T1 and T2 are connected to a power line that supplies a reference voltage, and the gate of the first NMOS transistor T1 is connected to a reset line that supplies a reset signal.

Also, the source of the third NMOS transistor T3 is connected to the drain of the second NMOS transistor, and the drain of the third NMOS transistor T3 is connected to a reading circuit (not shown) through a signal line. The gate of the third NMOS transistor T3 is connected to a column selection line that supplies a selection signal SLCT.

Accordingly, the first NMOS transistor T1 is a reset transistor Rx, and the second NMOS transistor T2 is a drive transistor DX. The third NMOS transistor T3 is a selection transistor Sx.

FIG. 2 is a layout view showing a unit pixel of a 3T type CMOS image sensor according to the related art.

As shown in FIG. 2, an active region 10 is defined in the unit pixel of 3T type CMOS image sensor. One photodiode 20 is formed at a wider part of the active region 10, and gate electrodes 30, 40, and 50 of the three transistors are formed overlapping a remaining part of the active region 10.

Namely, a reset transistor Rx is formed by the first gate electrode 30, a drive transistor Dx is formed by the second gate electrode 40, and a select transistor Sx is formed by the third gate electrode 50.

Here, impurity ions are implanted in the active region for lower portions of the gate electrodes 30, 40, and 50 and the photodiode region to form source/drain regions of each transistor.

A power source voltage Vdd may be applied to source/drain regions between the reset transistor Rx and the drive transistor Dx, and the source/drain regions at one side of the select transistor Sx are coupled to a reading circuit.

Although they are not shown, the gate electrodes 30, 40, and 50 are connected to respective signal lines, and the respective signal lines are connected to an external drive circuit by a pad at one end thereof.

FIG. 3 is a layout showing an impurity implantation region in a CMOS image sensor according to the related art.

As shown in FIG. 3, N-type ions are implanted at a concentration of at least 1×10¹⁵ ions/cm² into the gate electrodes 30,40, and 50 and the active region 10 except for the photodiode region 20 to form high concentration n⁺ type diffusion regions 70.

As shown in FIG. 3, so as to form an ohmic resistor for contact at the photodiode region 20, n⁺ type impurity ions are implanted therein. During a process for implanting high concentration n⁺ type impurity ions in the gate electrode 30, the impurity ions can be partially implanted in the photodiode region 20 by a mask error.

However, in a pixel array of 3T structure, in order to form an ohmic resistor for a contact for connecting the drive transistor Dx and the photodiode region 20 to each other, a sufficient amount of ions needs to be implanted. In contrast to this, in order to increase the capacitance of the photodiode, the ions need to be implanted at a minimum. Accordingly, a compromise is needed.

### BRIEF SUMMARY

Embodiments of the present invention are directed to a CMOS image sensor and a method for manufacturing the same that substantially obviates one or more problems due to limitations and/or disadvantages of the related art.

An object of a preferred embodiment of the present invention is to provide a CMOS image sensor with an enhanced photosensitivity by changing a position of a contact formed at a photodiode region to prevent a reduction of a capacitance caused by a high concentration implantation, and a method for manufacturing the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS (complementary metal oxide semiconductor) image sensor comprising: a semiconductor substrate in which an active region and a device isolation region are defined; a photodiode region comprising a first region and a second region formed at the active region, where impurity ions of a first conductivity type and impurity ions of a second conductivity type are implanted in the first region, and the impurity ions of the first conductivity type are implanted in the second region; and a transistor and an impurity diffusion region of the first conductivity formed at a transistor region of the active region.

In another aspect of the present invention, there is provided a method for manufacturing a CMOS image sensor comprising: forming a device isolation layer on a semiconductor substrate to define a device isolation region and an active region; forming a gate insulating layer and a polysilicon layer on the semiconductor substrate; selectively removing the polysilicon layer and the gate insulating layer to form a gate electrode; implanting impurity ions of a first conductivity type in a first region of a photodiode region of the active region; implanting impurity ions of the first conductivity type in a second region of the photodiode region and a transistor region of the active region; and implanting impurity ions of a second conductivity type in the second region of the photodiode region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is an equivalent circuit diagram of a 3T type CMOS image sensor according to the related art.

FIG. 2 is a layout view showing a unit pixel of a 3T type CMOS image sensor according to the related art.

FIG. 3 is a layout view showing an impurity implantation region in a CMOS image sensor according to the related art.

FIG. 4 is a layout view showing a unit pixel of a 3T type CMOS image sensor according to an embodiment of the present invention.

FIG. 5 is a layout view showing an implantation region for a contact formed in a photodiode in the CMOS image sensor according to an embodiment of the present invention.

FIG. 6 is a layout view showing a unit pixel of a 3T type CMOS image sensor according to an embodiment of the present invention.

FIG. 7 is a layout view showing an implantation region for a contact formed in a photodiode in the CMOS image sensor according to an embodiment of the present invention.

FIGS. 8A through FIG. 8E are cross-sectional views showing a method for manufacturing a CMOS image sensor according to an embodiment of the present invention.

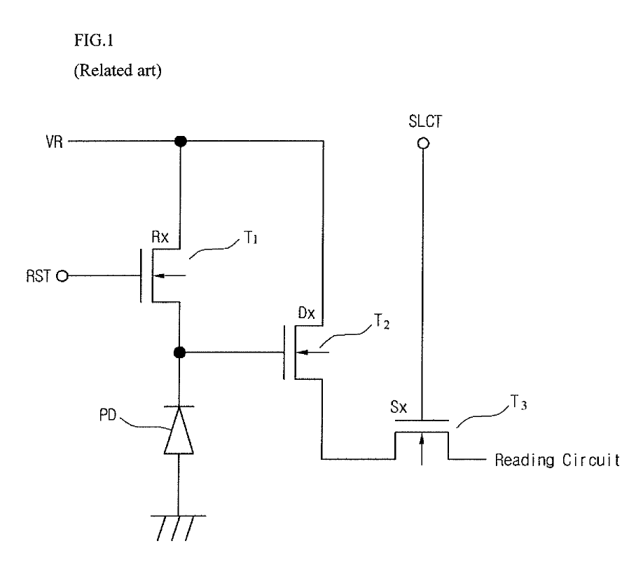

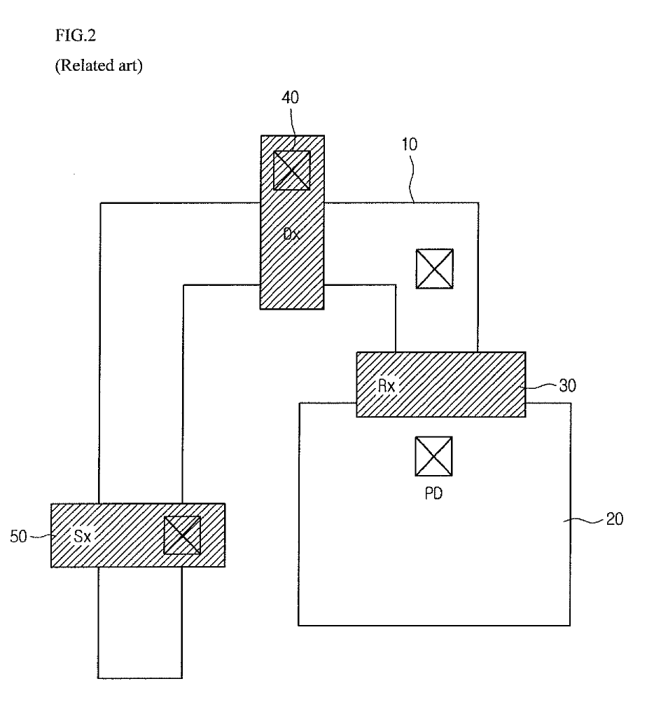

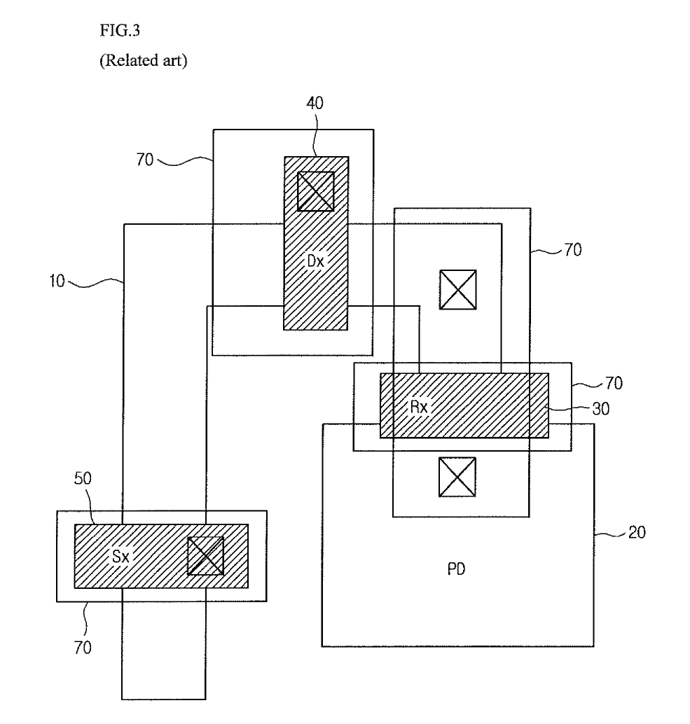

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

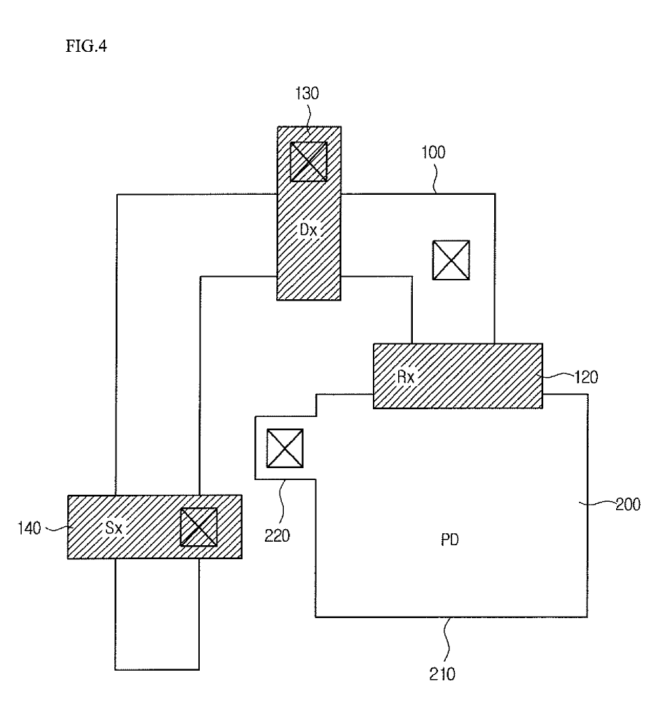

FIG. 4 is a layout view showing a unit pixel of a 3T type CMOS image sensor according to an embodiment of the present invention.

As shown in FIG. 4, a photodiode region 200 is formed at an active region defined in a semiconductor substrate. The photodiode region 200 is divided into a first protrusion region 210 and a second protrusion region 220. Gate electrodes 120, 130, and 140 of the three transistors can be formed overlapping a remaining portion of the active region 100.

A reset transistor Rx can be formed by the first gate electrode 120, a drive transistor Dx can be formed by the second gate electrode 130, and a select transistor Sx can be formed by the third gate electrode 140.

Here, impurity ions can be implanted in parts of the active region 100 for each transistor except for below the gate electrodes 120, 130, and 140 to form source/drain regions of each transistor.

The second protrusion region 220 of the photodiode region 200 can be formed near the select transistor Sx, and a contact can be formed at the second protrusion region 220, which is to be connected to the drive transistor Dx. In one embodiment, the second protrusion region 220 can be formed to be adjacent to the select transistor Sx.

The first protrusion region 210 of the photodiode region 200 can be used as a channel formation part of the reset transistor Rx.

Accordingly, a power source voltage Vdd can be applied to source/drain regions between the reset transistor Rx and the drive transistor Dx, and a reading circuit can be coupled to source/drain regions at one side of the select transistor Sx.

The gate electrodes 120, 130, and 140 can be connected to respective signal lines, and the respective signal lines can be connected to an external drive circuit through a pad at one end thereof.

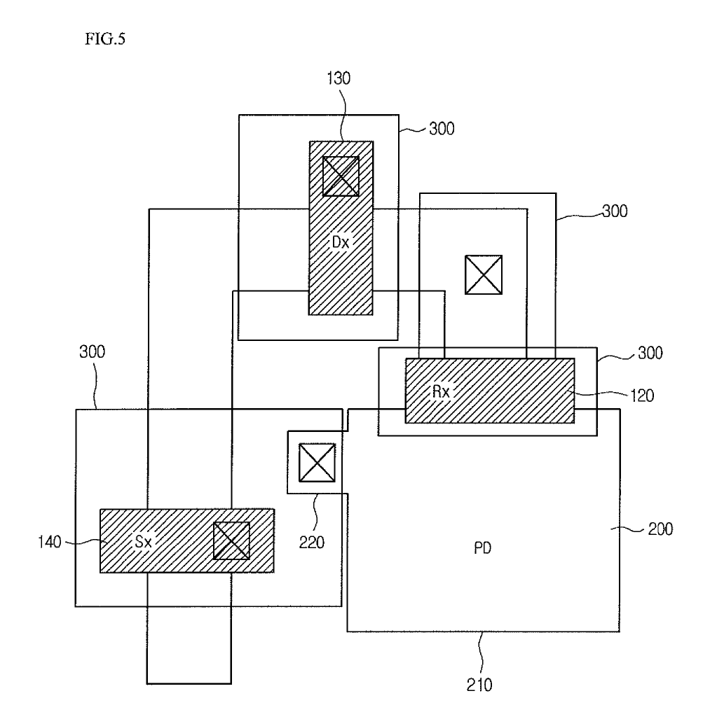

FIG. 5 is a view showing an implanted state of impurity ions in order to make an ohmic resistor contact on a photodiode region according to an embodiment of the present invention.

As shown in FIG. 5, N-type ions can be implanted at a concentration of at least 1×10¹⁵/cm² in the active region 100 of the gate electrodes 120, 130, and 140. The N-type ions are also implanted into the second protrusion region 220 of the photodiode region 200 so as to make a contact formed in the photodiode region 200 with an ohmic resistor. The ion implantation forms high concentration n⁺ type diffusion regions 300.

Namely, the high concentration n⁺ type diffusion region 300 formed at the second protrusion region 220 of the photodiode region 200 is formed in the vicinity of the select transistor Sx in such a way that a part of the same high concentration n⁺ type diffusion region 300 overlaps with source/drain ion implantation regions of the select transistor Sx.

That is, impurity ions are implanted in the second protrusion region 220 of the photodiode region 200 through an opening of a mask for implanting the impurity ions in the select transistor Sx.

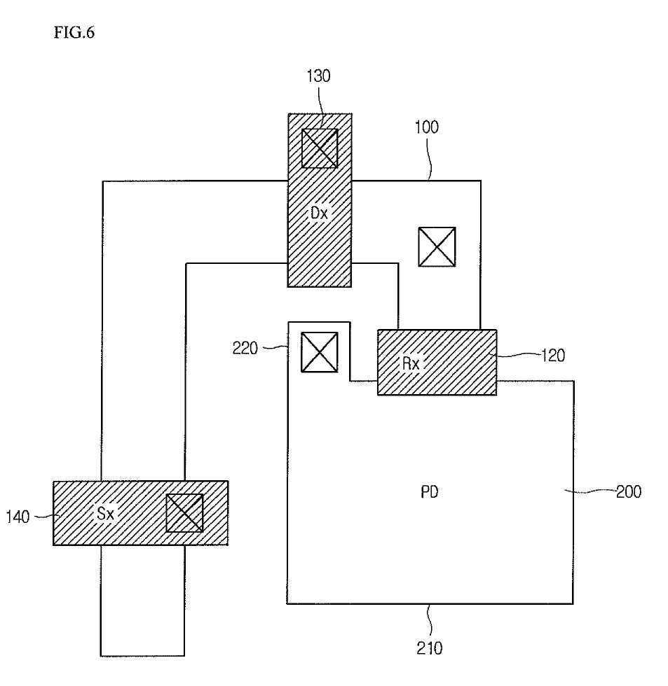

FIG. 6 is a layout view showing a unit pixel of a 3T type CMOS image sensor according to another embodiment of the present invention.

As shown in FIG. 6, an active region 100 is defined in the semiconductor substrate. A photodiode region 200 is formed on a portion of the active region 100 and is divided into a first protrusion region 210 and a second protrusion region 220. Gate electrodes 120, 130, and 140 of three transistors are formed overlapping a remaining part of the active region 100.

The first gate electrode 120 constitutes a reset transistor Rx, the second gate electrode 103 constitutes a drive transistor Dx, and the third gate electrode 140 constitutes a select transistor Sx.

Here, impurity ions can be implanted in the remaining part of the active region 100 except for below the gate electrodes 120, 130, and 140 to form source/drain regions of each transistor.

The second protrusion region 220 of the photodiode region 200 can be formed in the vicinity of the drive transistor Dx, and a contact can be formed at the second protrusion region 220, which is to be connected to the drive transistor Dx.

The first protrusion region 210 of the photodiode region 200 can be used as a channel formation part of the reset transistor Rx.

Accordingly, a power source voltage Vdd can be applied to source/drain regions between the reset transistor Rx the drive transistor Dx, and source/drain regions at one side of the select transistor Sx can be coupled with a reading circuit.

The gate electrodes 120, 130, and 140 can be connected to respective signal lines, and the respective signal lines can be connected to an external drive circuit through a pad at one end thereof.

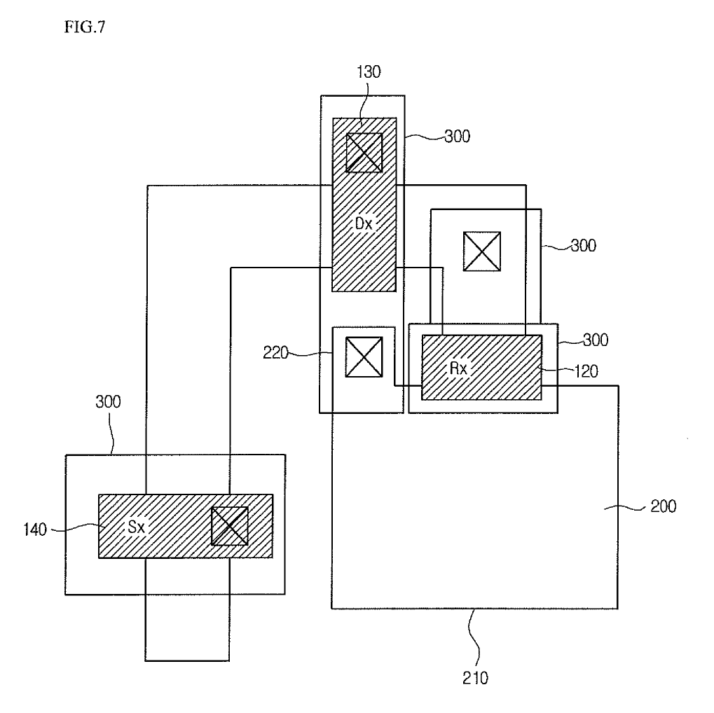

FIG. 7 is a layout view showing an implanted state of impurity ions in order to make an ohmic resistor contact formed on a photodiode region according to an embodiment of the present invention.

As shown in FIG. 7, N-type ions can be implanted at a concentration of at least 1×10¹⁵/cm² in the active region 100 of the gate electrodes 120, 130, and 140. The N-type ions are also implanted into the second protrusion region 220 formed in the vicinity of the drive transistor Dx so as to make a contact formed in the photodiode region 200 with an ohmic resistor. The ion implantation forms high concentration n⁺ type diffusion regions 300.

Namely, the high concentration n⁺ type diffusion region 300 formed at the second protrusion region 220 of the photodiode region 200 is formed in the vicinity of the drive transistor Dx in such a way that a part of the same high concentration n⁺ type diffusion region 300 overlaps with source/drain ion implantation regions of the select transistor Dx.

That is, impurity ions are implanted in the second protrusion region 220 of the photodiode region 200 through an opening of a mask for implanting the impurity ions in the drive transistor Dx.

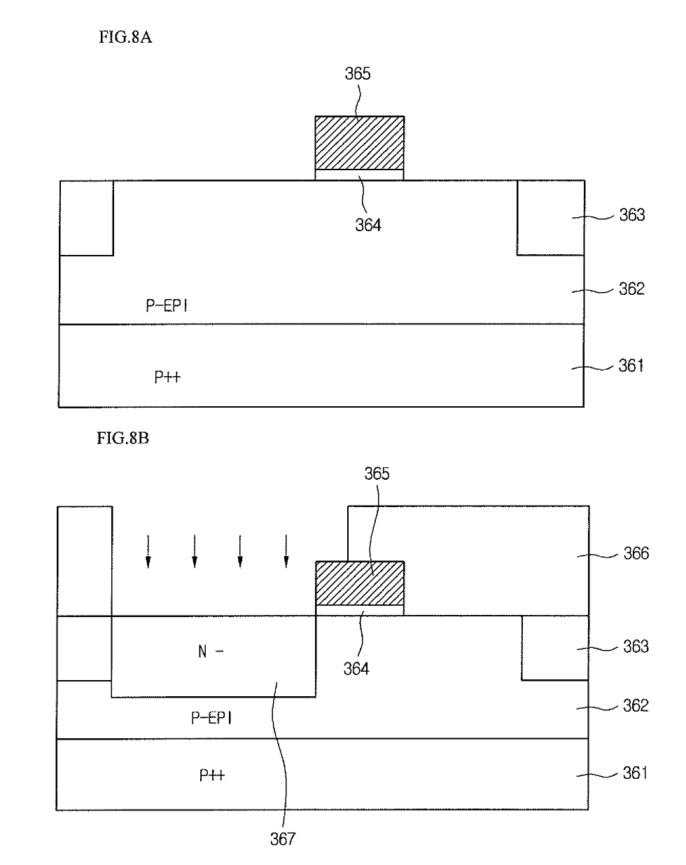

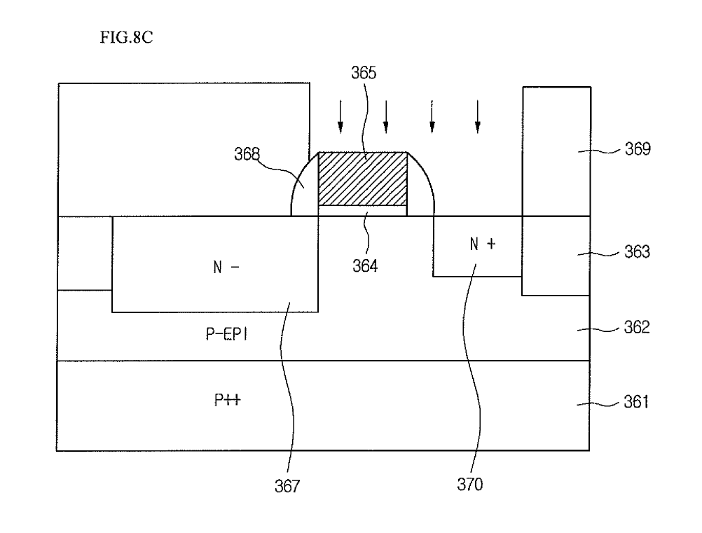

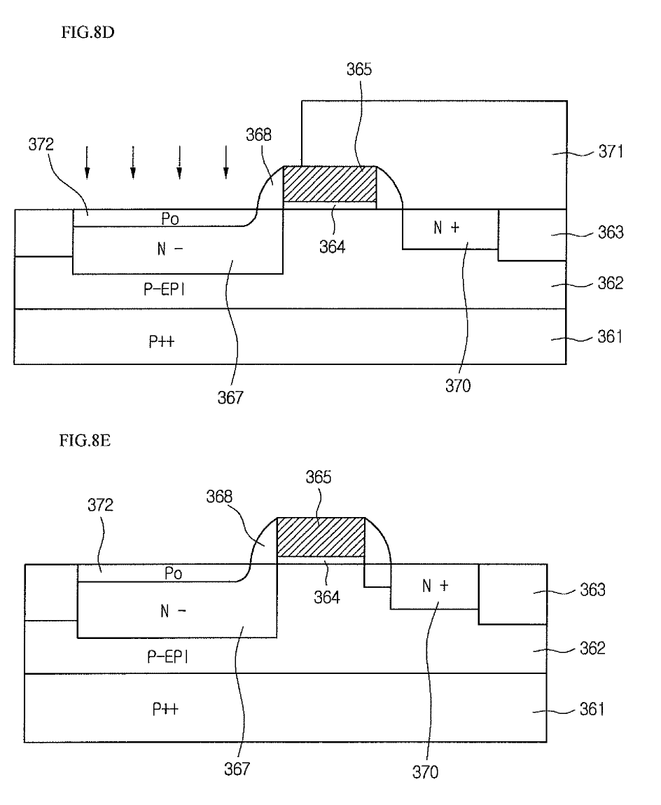

FIGS. 8A to 8E are cross-sectional views showing a method for manufacturing a CMOS image sensor according to an embodiment of the present invention.

Referring to FIG. 8A, an epitaxial process can be carried out for a high concentration P⁺⁺ type semiconductor substrate 361 to form a low concentration P⁻ type epitaxial layer 362.

Next, an active region and a device isolation region can be defined on the semiconductor substrate 361, and a device isolation layer 363 can be formed in the device isolation region using an STI process or an LOCOS process.

Then a gate insulating layer 364 and a conductive layer (for example, a high concentration polysilicon layer) can be sequentially deposited on an entire surface of the epitaxial layer 362. Then, the conductive layer and the gate insulating layer can be selectively removed to form a gate electrode 365.

Referring to FIG. 8B, a first photoresist layer 366 can be coated on an entire surface of the semiconductor substrate 361 and patterned by exposure and developing processes to expose blue, green, and red photodiode regions.

Then, using the patterned first photo resist layer 366 as a mask, low concentration n⁻ type impurity ions can be implanted in the epitaxial layer 362 to form blue, green, and red photodiode regions.

Each photodiode region 367 can also function as a source region of the reset transistor Rx.

When a reverse bias is applied to the photodiode region 267, a depletion region is produced between the photodiode region 267 and the low concentration P⁻ type epitaxial layer 362. In operation, when the reset transistor is turned-off, electrons generated by the light incident the photodiode reduce a potential of the drive transistor. The potential continues to reduce from the turning-off of the reset transistor to after the turning-on of the reset transistor, which causes a voltage difference. The voltage difference is used in the signal processing for the image sensor.

In a specific embodiment the respective photodiode regions 367 have the same depth ranging from about 2 to about 3 μm.

That is, impurity ions are implanted in the respective photodiode regions 367 with the same ion implantation energy to have the same depth.

Referring to FIG. 8C, the first photo resist layer 366 can be completely removed, and an insulating layer can be deposited on an entire surface of the semiconductor substrate 361. Next, an etch back process can be performed to form sidewall insulating layers 368 at both sides of the gate electrode 365.

Thereafter, the entire surface of the semiconductor substrate 361 can be coated with a second photo resist layer 369, and the second photoresist layer 369 can be patterned using exposure and developing processes to cover the photodiode regions and expose source/drain regions and the gate electrode 364 of each transistor.

Here, the second photo resist layer 369 covers a first protrusion region of the photodiode region 367, but exposes a second protrusion region of the photodiode region 367.

High concentration n⁺ type impurity ions can be implanted in the exposed source/drain regions, the second protrusion region and the gate electrode 364 using the second patterned photo resist layer 369 as a mask to form n⁺ type diffusion region 370.

Referring to FIG. 8D, the second photo resist layer 369 can be removed and a third photoresist layer 371 can be coated on an entire surface of the semiconductor substrate 361 and patterned to expose the first protrusion region of each photodiode region 367 by exposure and developing processes.

Next, using the third patterned photo resist layer 371 as a mask, p⁰ type impurity ions can be implanted in the first protrusion region of the photodiode region 367 in which an n⁻ type diffusion region 367 is formed in order to form a p⁰ type diffusion region 372 on a surface of the semiconductor substrate.

In a specific embodiment the p⁰ type diffusion region 372 can be formed to have a depth within 0.1 μm.

Referring to FIG. 8E, the third photo resist layer 371 can be removed, and a thermal treatment process can be performed to diffuse each impurity diffusion region.

As is evident from the above explanation, the CMOS image sensor according to embodiments of the present invention has following effects.

Namely, in the 3T type CMOS image sensor, since the concentration of an N-type conductive material of a photodiode implanted in a contact formation position for connecting a drive transistor and a photodiode region can be adjusted separately from the photodiode, a capacitance reduction due to the implantation of a high concentration impurity ion in the photodiode region can be prevented in order to enhance the photosensitivity of the image sensor.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide semiconductor) image sensor comprising:
a semiconductor substrate in which an active region and a device isolation region are defined;
a photodiode region comprising a first region and a second region formed on a photodiode area of the active region, wherein the first region has impurity ions of a first conductivity type and impurity ions of a second conductivity type implanted therein, and the second region has impurity ions of the first conductivity type implanted therein; and
a transistor and an impurity diffusion region of a first conductivity type formed on a transistor region of the active region.

2. The CMOS image sensor according to claim 1, wherein a contact is formed on the second region.

3. The CMOS image sensor according to claim 1, wherein the first region is connected to the second region and the transistor.

4. The CMOS image sensor according to claim 1, wherein the first region is adjacent to a channel part of the transistor.

5. The CMOS image sensor according to claim 1, wherein the second region extends from a portion of the first region.

6. A method for manufacturing a CMOS (complementary metal oxide semiconductor) image sensor comprising:
forming a device isolation layer on a semiconductor substrate to define a device isolation region and an active region;
forming a gate insulating layer and a polysilicon layer on the semiconductor substrate;
selectively removing a portion of the polysilicon layer and the gate insulating layer to form a gate electrode;
implanting impurity ions of a first conductivity type in a first region of a photodiode region of the active region;
implanting impurity ions of the first conductivity type in a second region of the photodiode region and a transistor region of the active region; and
implanting impurity ions of a second conductivity type in the first region of the photodiode region.

7. The method according to claim 6, further comprising forming insulating layer sidewalls at both sides of the gate electrode.

8. The method according to claim 6, wherein the gate insulating layer is formed by a thermal oxidizing process or a chemical vapor deposition (CVD) method.

9. The method according to claim 6, wherein the impurity ions of the first conductivity type are implanted in the second region through an opening of a mask to implant the impurity ions of the first conductivity type in a select transistor of the transistor region.

10. The method according to claim 6, wherein the impurity ions of the first conductivity type are implanted in the second region through an opening of a mask to implant the impurity ions of the first conductivity type in a drive transistor of the transistor region.
